(19) United States
(12) Patent Application Publication
(10) Pub. No.: US 2024/0145634 A1
(43) Pub. Date: May 2, 2024

(54) DISPLAY DEVICE

(71) Applicant: LG DISPLAY CO., LTD., Seoul (KR)

(72) Inventors: Daeyoung SEO, Seoul (KR); Hun JANG, Paju-si (KR)

(73) Assignee: LG DISPLAY CO., LTD., SEOUL (KR)

(21) Appl. No.: 18/381,757

(22) Filed: Oct. 19, 2023

(30) Foreign Application Priority Data
Oct. 31, 2022 (KR) 10-2022-0142147

(51) Int. Cl. H01L 33/38; H01L 25/075; H01L 25/16; H01L 33/62

(52) U.S. Cl. CPC H01L 33/387; H01L 25/0753; H01L 25/167; H01L 33/62

(57) ABSTRACT

A display device includes a substrate including a plurality of sub pixels; a first lower assembly electrode in the plurality of sub pixels; a first assembly line in the plurality of sub pixels and disposed on a layer different from that of the first lower assembly electrode; a light emitting diode on the first lower assembly electrode and the first assembly line and including a first electrode, a semiconductor layer, and a second electrode; and a second lower assembly electrode between the first lower assembly electrode and the light emitting diode and electrically connected to the first electrode or the second electrode.

### CROSS-REFERENCE TO RELATED APPLICATION

This application claims the priority of Korean Patent Application No. 10-2022-0142147 filed on Oct. 31, 2022, which is hereby incorporated by reference in its entirety.

### BACKGROUND

### Field of the Disclosure

The present disclosure relates to a display device, and more particularly, to a display device which self-assembles a light emitting diode (LED).

### Description of the Background

As display devices which are used for a monitor of a computer, a television, or a cellular phone, there are an organic light emitting display (OLED) device which is a self-emitting device, a liquid crystal display device (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance may be displayed.

### SUMMARY

Accordingly, the present disclosure is directed to a display device that substantially obviates one or more of problems due to limitations and disadvantages described above.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

More specifically, the present disclosure is to provide a display device in which a lower assembly electrode which is in direct contact with a light emitting diode is disposed under the light emitting diode and is connected to a power line to improve a lighting ratio of the light emitting diode.

The present disclosure is not limited to the above-mentioned features and other features, which are not mentioned above, may be clearly understood by those skilled in the art from the following descriptions.

To achieve these and other advantages and in accordance with the present disclosure, as embodied and broadly described, a display device includes a substrate including a plurality of sub pixels; a first lower assembly electrode in the plurality of sub pixels; a first assembly line in the plurality of sub pixels and disposed on a layer different from that of the first lower assembly electrode; a light emitting diode on the first lower assembly electrode and the first assembly line and including a first electrode, a semiconductor layer, and a second electrode; and a second lower assembly electrode between the first lower assembly electrode and the light emitting diode and electrically connected to the first electrode or the second electrode. Accordingly, an assembly rate of the light emitting diode is improved and a resistance of a power line is reduced to improve a lighting rate.

In another aspect of the present disclosure, a display device includes a substrate including a plurality of sub pixels; a first assembly line and a second assembly line disposed in parallel in the plurality of sub pixels; a light emitting diode disposed to overlap with the first assembly line or the second assembly line; and a first lower auxiliary electrode and a second lower auxiliary electrode overlapping with the light emitting diode and any one of the first assembly line and the second assembly line, under the light emitting diode. Accordingly, an assembly rate of the light emitting diode is improved and a resistance of a power line is reduced to improve a lighting rate.

Other detailed matters of the exemplary aspects are included in the detailed description and the drawings.

According to the exemplary aspects of the present disclosure, assembly electrodes disposed in assembly grooves are disposed on different layers to improve an intensity of an electric field for assembling the light emitting diode.

Further, according to the exemplary aspects of the present disclosure, a first electrode of the light emitting diode and a lower assembly electrode are in direct contact with each other so that the light emitting diode may be fixed onto the substrate after assembling the light emitting diode.

Further, according to the exemplary aspects of the present disclosure, the auxiliary electrode is connected to a power line to reduce a resistance of the power line and improve a lighting ratio of the light emitting diode.

Further, according to the exemplary aspects of the present disclosure, the light emitting diode is disposed in the planarization layer to reduce a thickness of the planarization layer disposed over the light emitting diode.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary aspect of the present disclosure;

FIG. 2 is a schematic plan view of a display panel included in a display device according to an exemplary aspect of the present disclosure;

FIG. 3 is an enlarged plan view of a display device according to an exemplary aspect of the present disclosure;

FIG. 4 is a cross-sectional view taken along lines A-A′ and B-B′ of FIG. 2;

FIG. 5 is a cross-sectional view taken along lines A-A′ and C-C′ of FIG. 2; and

FIGS. 6A and 6B are cross-sectional views for explaining a manufacturing process of a display device according to an exemplary aspect of the present disclosure.

### DETAILED DESCRIPTION

Advantages and characteristics of the present disclosure and a method of achieving the advantages and characteristics will be clear by referring to exemplary aspects described below in detail together with the accompanying drawings. However, the present disclosure is not limited to the exemplary aspects disclosed herein but will be implemented in various forms. The exemplary aspects are provided by way of example only so that those skilled in the art may fully understand the disclosures of the present disclosure and the scope of the present disclosure.

The shapes, sizes, ratios, angles, numbers, and the like illustrated in the accompanying drawings for describing the exemplary aspects of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated.

The features of various aspects of the present disclosure may be partially or entirely adhered to or combined with each other and may be interlocked and operated in technically various ways, and the aspects may be carried out independently of or in association with each other.

Hereinafter, the present disclosure will be described in detail with reference to accompanying drawings.

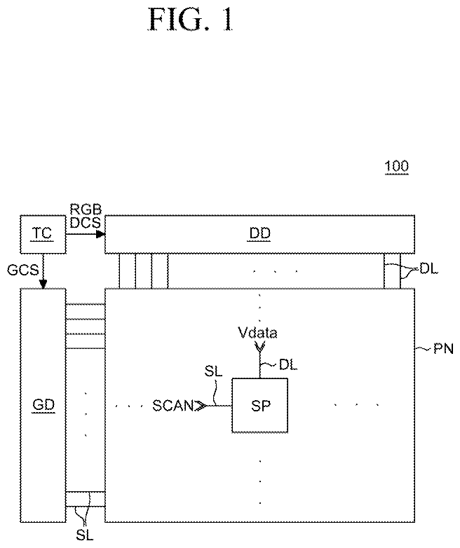

FIG. 1 is a schematic plan view of a display device according to an exemplary aspect of the present disclosure.

In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, each of the plurality of sub pixels SP may be connected to a high potential power line VL1, a low potential power line VL2, a reference line VL3, and the like.

The plurality of sub pixels SP is a minimum unit which configures a screen and each of the plurality of sub pixels SP includes a light emitting diode and a pixel circuit for driving the light emitting diode. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

The gate driver GD supplies a plurality of scan signals SCAN to a plurality of scan lines SL in accordance with a plurality of gate control signals GCS supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data RGB input from the timing controller TC in accordance with a plurality of data control signals DCS supplied from the timing controller TC into a data voltage Vdata using a reference gamma voltage. The data driver DD may supply the converted data voltage Vdata to the plurality of data lines DL.

The timing controller TC aligns image data RGB input from the outside to supply the image data to the data driver DD. The timing controller TC may generate a gate control signal GCS and a data control signal DCS using synchronization signals input from the outside, such as a dot clock signal, a data enable signal, and horizontal/vertical synchronization signals. Further, the timing controller TC supplies the generated gate control signal GCS and data control signal DCS to the gate driver GD and the data driver DD, respectively, to control the gate driver GD and the data driver DD.

Hereinafter, a display panel PN of a display device 100 according to an exemplary aspect of the present disclosure will be described in more detail.

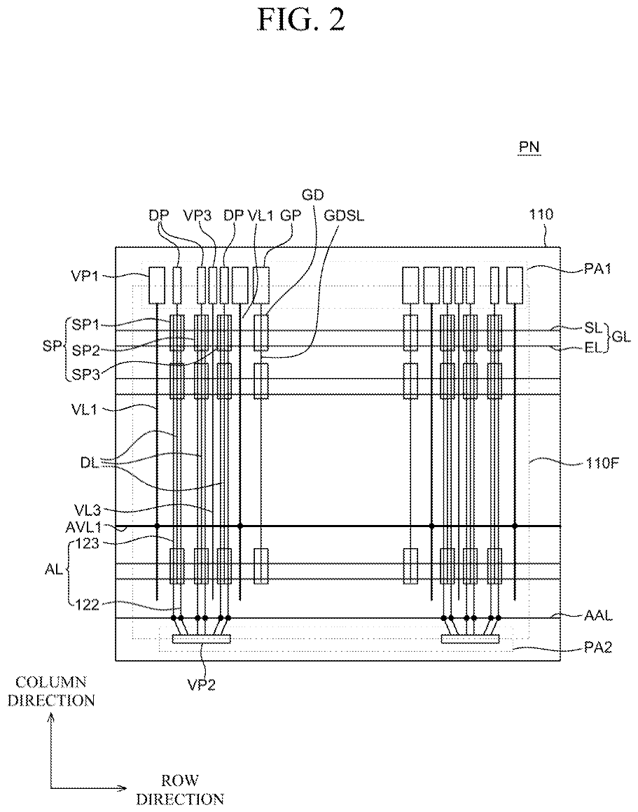

FIG. 2 is a schematic plan view of a display panel included in a display device according to an exemplary aspect of the present disclosure. In FIG. 2, for the convenience of description, among various components of the display device 100, only a substrate 110, a plurality of pixels PX, a pad, and wiring lines are illustrated.

The substrate 110 is a component for supporting various components included in the display panel PN and may be formed of an insulating material. For example, the substrate 110 may be formed of glass or resin. Further, the substrate 110 may be configured to include polymer or plastics or may be formed of a material having flexibility.

The substrate 110 is divided into an active area and a non-active area and the active area is an area in which a plurality of pixels PX is disposed to display images. The plurality of pixels PX may include at least two or more sub pixels. In the drawings, even though it is illustrated that the plurality of pixels PX includes three sub pixels SP1, SP2, and SP3, it is not limited thereto. Three sub pixels includes a first sub pixel SP1, a second sub pixel SP2, and a third sub pixel SP3. Hereinafter, any one sub pixel among three sub pixels is denoted by SP.

Each of the plurality of sub pixels SP is an individual unit which emits light and in each of the plurality of sub pixels SP, a light emitting diode 120 and a pixel circuit are formed. The unit pixel including three sub pixels SP1, SP2, and SP3 includes a red sub pixel, a green sub pixel, and a blue sub pixel, or sub pixels which emits at least two color light, among the red sub pixel, the green sub pixel, the blue sub pixel, and the white sub pixel, but is not limited thereto. The unit pixel may include at least two or more sub pixels including a light emitting diode having a lowest efficiency, among a red light emitting diode, a green light emitting diode, and a blue light emitting diode.

The display device 100 according to the exemplary aspect of the present disclosure includes a first sub pixel SP1 emitting red light, a second sub pixel SP2 emitting green light, and a third sub pixel SP3 emitting blue light. The first sub pixel SP1, the second sub pixel SP2, and the third sub pixel SP3 may be disposed in parallel in the row direction.

As mentioned above, the active area is an area in which a plurality of unit pixels is disposed and the non-active area is an area in which an image is not displayed and the plurality of unit pixels is not disposed. That is, a gate driver GD for driving the plurality of sub pixels SP disposed in the active area, a wiring line, a pad for applying signals to wiring lines are disposed in the non-active area.

The gate driver GD supplies a gate signal to the plurality of sub pixels SP through the gate line GL. The gate signal includes a scan signal and an emission signal. The scan signal is supplied through the scan line SL and the emission signal is supplied through the emission line EL. Further, the scan line SL and the emission line EL may be collectively referred to as gate lines GL.

The gate driver GD includes a scan driver which supplies a scan signal and an emission driver which supplies an emission signal.

In the display device 100 according to the exemplary aspect of the present disclosure, the gate driver GD is divided into a plurality of areas on the substrate 110 to be disposed between the plurality of pixels PX.

In the display device 100 according to the exemplary aspect of the present disclosure, the light emitting diode may be an LED (light emitting diode or an inorganic light emitting diode). The LED has excellent luminous efficiency so that an area occupied by the LED with respect to the area of the sub pixel SP may be very small. Accordingly, an LED and a pixel circuit for driving the LED are disposed in every sub pixel SP and the gate driver GD may be disposed in the non-active area in at least one sub pixel SP or at least every unit pixel.

The gate driver GD of FIG. 2 is disposed in every two unit pixels to supply a gate signal to sub pixels SP disposed in the same row as the gate driver GD. For example, the gate driver GD may be disposed between a blue emission sub pixel and a red emission sub pixel. However, it is not limited thereto and in some cases, a placement density of the gate driver GD may vary.

Further, a scan driver and an emission driver included in the gate driver GD are disposed in the same row, but may be disposed in different areas.

The data driver DD converts image data into a data signal and supplies the converted data signal to the sub pixel SP through the data line DL. The data driver DD may be formed on a rear surface of the substrate 110 or may be formed on a separate substrate. When the data driver DD is formed on one surface of a separate substrate, the other surface on which the data driver DD is not formed and a rear surface of the substrate 110 may be bonded to be opposite to each other. To electrically connect the front surface and the rear surface of the substrate 110 or electrically connect the front surface of the substrate 110 and the other surface of the separate substrate, a side line is disposed on a side surface of the substrate 110 or a separate substrate from the substrate 110. Accordingly, the data driver disposed on the rear surface of the substrate 110 or on the other surface of the separate substrate may supply a data signal to the sub pixel SP through the side line.

As described above, in the display device 100 according to the exemplary aspect of the present disclosure, the gate driver GD may be disposed between adjacent unit pixels on the substrate 110. However, it is not limited thereto and the gate driver GD may be disposed on one side or both sides of the substrate 110.

In the meantime, the gate line GL is disposed in the row direction on the substrate 110 and the data line DL may be disposed in the column direction. The gate line GL and the data line DL are disposed in all the sub pixels SP to supply signals to the pixel circuit disposed in the sub pixel SP.

Pad areas PA1 and PA2 in which pads are disposed are formed on both sides of the substrate 110, that is, above and under the substrate 110 in the column direction. In this case, the pad area formed above the substrate 110 is referred to as the first pad area PA1 and the pad area formed under the substrate 110 is referred to as the second pad area PA2. In the substrate 110, the first pad area PA1 and the second pad area PA2 are opposite to each other.

In the first pad area PA1, a data pad DP connected to the data line DL, a gate pad GP connected to the gate driver GD, a high potential voltage pad VP1 connected to a high potential voltage line VL1, and a reference voltage pad VP3 connected to a reference voltage line VL3 may be disposed. In this case, the data pad is disposed as many as the number of the sub pixels SP included in the unit pixel.

In the gate driver GD, a wiring line which supplies various clock signals, a wiring line which supplies a gate low voltage, and a wiring line which supplies a gate high voltage are disposed to transmit signals. The gate drivers GD are disposed in parallel in the column direction so that wiring lines which transmit signals to the gate driver GD are aligned with the gate driver GD. The wiring lines which transmit signal to the gate driver GD are referred to as gate driving lines GDSL and the gate driving lines GDSL are disposed in the column direction and are connected to the gate pad GP disposed in the first pad area PA1 to be supplied with a signal from the gate pad GP.

The high potential voltage line VL1 may be disposed in the column direction for every unit pixel or every sub pixel SP. Even though it is illustrated that the high potential voltage lines are disposed at a left/right side in every unit pixel PX in the drawings, it is not limited thereto. The high potential voltage line VL1 disposed in the column direction supplies a high potential voltage to the plurality of sub pixels SP through a high potential voltage pad VP1 in the first pad area PA1. The plurality of high potential voltage lines VL1 disposed in the column direction is connected to auxiliary high potential voltage lines AVL1 disposed in the row direction to form a mesh structure. An auxiliary high potential voltage line AVL1 may be disposed in every row in which the sub pixel SP is disposed or every plurality of rows. The auxiliary high potential voltage line AVL1 suppress the voltage drop of the high potential voltage line VL1 and may supply a high potential voltage to the plurality of sub pixels SP.

In the second pad area PA2, a low potential voltage pad VP2 connected to the low potential voltage line may be disposed. In this case, an assembly line AL for self-assembling the light emitting diode is used as a low potential voltage line after assembling the light emitting diode.

Two assembly lines AL may be disposed in the column direction in every sub pixel SP. The assembly line AL includes a first assembly line 122 and a second assembly line 123. The assembly line AL disposed in the column direction supplies a low potential voltage to the plurality of sub pixels SP through a low potential voltage pad VP2 in the second pad area PA2. A plurality of low potential voltage pads VP2 is disposed and may be disposed in at least every two assembly lines.

The plurality of assembly lines AL disposed in the column direction is connected to the auxiliary low potential voltage line AAL disposed in the row direction before being connected to the low potential voltage pad VP2. In the drawing, even though the auxiliary low potential voltage line AAL is illustrated only on one side surface of the substrate 110, it is not limited thereto and may be disposed on at least one side surface of the substrate 110. Additionally, wiring lines for connecting the plurality of assembly lines AL may be disposed in the row direction in every row or every plurality of rows in which the sub pixel SP is disposed. Accordingly, the auxiliary low potential voltage line AAL suppress the voltage drop of the assembly line AL and may supply a low potential voltage to the plurality of sub pixels SP.

The reference voltage line VL3 may be disposed in the column direction in every unit pixel disposed in the row direction. The reference voltage line VL3 disposed in the column direction supplies the reference voltage to the unit pixel through a row-direction line which is separately disposed. The reference voltage line VL3 is connected to the reference voltage pad VP3 disposed in the first pad area PA1 and the reference voltage is supplied to the plurality of reference voltage lines VL3 through the reference voltage pad VP3.

The display panel PN included in the display device 100 according to the exemplary aspect of the present disclosure may grind and remove the edge of the substrate 110 to reduce the bezel. The bezel is an edge area of the substrate 110 in which the sub pixel SP is not disposed. When the edge is ground, parts of the pad and the wiring line disposed at the edge of the substrate 110 are removed and the size of the substrate 110 is reduced to implement the display panel PN with a size of a final substrate 110F.

Specifically, most of the pads disposed in the first pad area PA1 and the second pad area PA2 is removed from the final substrate 110F so that only a part of the pads or a trace thereof may remain.

Hereinafter, the plurality of sub pixels SP will be described in more detail with reference to FIG. 2 together.

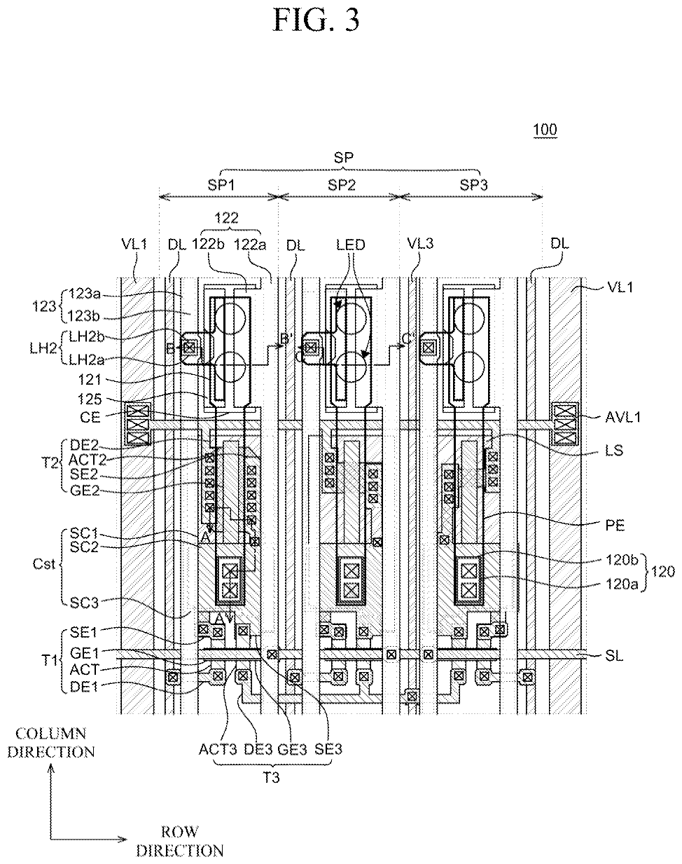

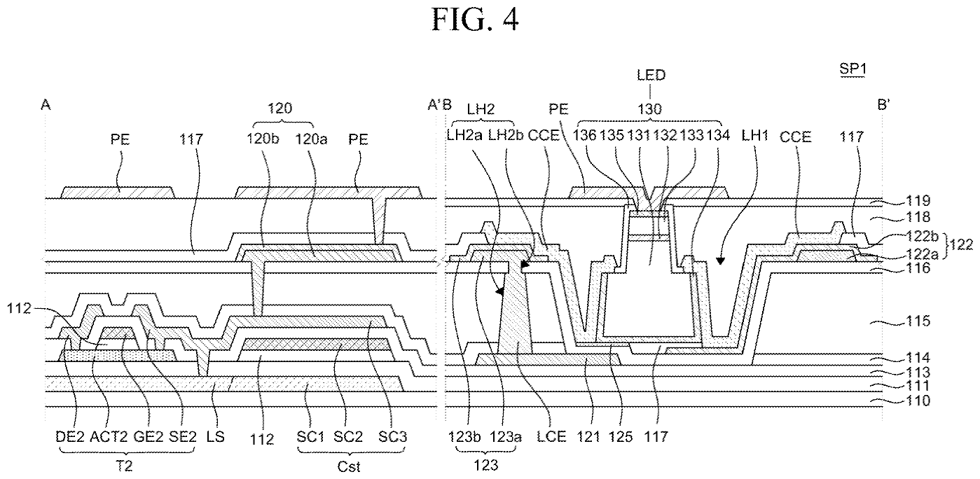

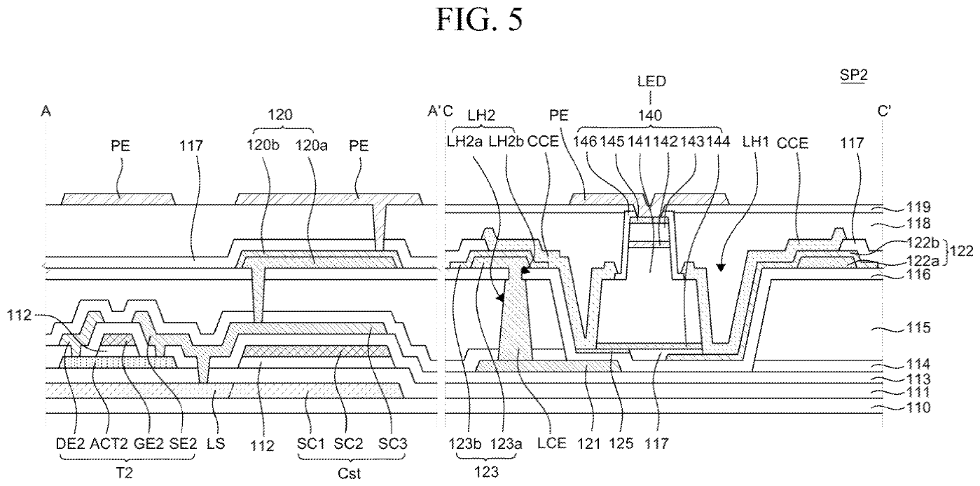

FIG. 3 is an enlarged plan view of a display device according to an exemplary aspect of the present disclosure. FIG. 4 is a cross-sectional view taken along lines A-A′ and B-B′ of FIG. 3. FIG. 5 is a cross-sectional view taken along lines A-A′ and C-C′ of FIG. 3. Referring to FIG. 3, each of the plurality of sub pixels SP includes a first transistor T1, a second transistor T2, a third transistor T3, a storage capacitor Cst, and one or more light emitting diodes LED. In FIG. 3, for the simplicity of the drawing, the hatching of the first clad layer 122b, the second clad layer 123b, the pixel electrode PE, and the light emitting diode LED is omitted and the contact electrode CE is not illustrated.

Referring to FIGS. 3 and 4, the plurality of sub pixels SP includes a first sub pixel SP1, a second sub pixel SP2, and a third sub pixel SP3. Each of the first sub pixel SP1, the second sub pixel SP2, and the third sub pixel SP3 includes a light emitting diode LED and a pixel circuit to independently emit light. For example, the first sub pixel SP1 is a red sub pixel, the second sub pixel SP2 is a green sub pixel, and the third sub pixel SP3 is a blue sub pixel, but it is not limited thereto.

The display panel PN includes a substrate 110, a buffer layer 111, a gate insulating layer 112, an interlayer insulating layer 113, a first passivation layer 114, a first planarization layer 115, a second passivation layer 116, a third passivation layer 117, and a second planarization layer 118.

A high potential power line VL1, a plurality of data lines DL, a reference line VL3, an assembly line AL, a light shielding layer LS, and a first capacitor electrode SC1 are disposed on the substrate 110.

The high potential power line VL1 is a wiring line which transmits a high potential power voltage to each of the plurality of sub pixels SP. The plurality of high potential power lines VL1 may transmit the high potential power voltage to a second transistor T2 of each of the plurality of sub pixels SP. The high potential power line VL1 may extend along a column direction between the plurality of sub pixels SP. For example, the high potential power line VL1 may be disposed along a column direction between the first sub pixel SP1 and the third sub pixel SP3. Further, the high potential power line VL1 may transmit a high potential power voltage to each of the plurality of sub pixels SP disposed in the row direction through the auxiliary high potential power line AVL1 to be described below. In this case, the high potential voltage line VL1 may be referred to as a first power line. Further, the column direction may be referred to as a first direction and the row direction may be referred to as a second direction.

The plurality of data lines DL is wiring lines which transmit the data voltage Vdata to each of the plurality of sub pixels SP. The plurality of data lines DL may be connected to the first transistor T1 of each of the plurality of sub pixels SP. The plurality of data lines DL may extend along a column direction between the plurality of sub pixels SP. For example, a data line DL which extends in the column direction between the first sub pixel SP1 and the high potential power line VL1 transmits a data voltage Vdata to the first sub pixel SP1. A data line DL disposed between the first sub pixel SP1 and the second sub pixel SP2 transmits a data voltage Vdata to the second sub pixel SP2. Further, a data line DL disposed between the third sub pixel SP3 and the high potential power line VL1 may transmit a data voltage Vdata to the third sub pixel SP3.

The reference lines VL3 is a wiring line which transmits a reference voltage to the plurality of sub pixels SP. The reference line VL3 may be connected to the third transistor T3 of each of the plurality of sub pixels SP. The reference line VL3 may extend along the column direction between the plurality of sub pixels SP. For example, the reference line VL3 may extend along the column direction between the second sub pixel SP2 and the third sub pixel SP3. Further, a third drain electrode DE3 of the third transistor T3 of each of the first sub pixel SP1, the second sub pixel SP2, and the third sub pixel SP3 adjacent to the reference line VL3 extends in the row direction to be electrically connected to the reference line VL3. In this case, the reference voltage line VL3 may be referred to as a third power line.

The light shielding layer LS is disposed on the substrate 110 in each of the plurality of sub pixels SP. The light shielding layer LS blocks light which is incident to the transistor from the lower portion of the substrate 110 to minimize a leakage current. For example, the light shielding layer LS may block light incident to a second active layer ACT2 of the second transistor T2 which is a driving transistor.

In each of the plurality of sub pixels SP, a first capacitor electrode SC1 is disposed on the substrate 110. The first capacitor electrode SC1 may form a storage capacitor Cst together with the other capacitor electrode. The first capacitor electrode SC1 may be integrally formed with the light shielding layer LS.

The buffer layer 111 is disposed on the high potential power line VL1, the plurality of data lines DL, the reference line VL3, the light shielding layer LS, and the first capacitor electrode SC1. The buffer layer 111 may reduce permeation of moisture or impurities through the substrate 110. The buffer layer 111 may be configured by a single layer or a double layer of silicon oxide (SiOx) or silicon nitride (SiNx), but is not limited thereto. However, the buffer layer 111 may be omitted depending on a type of substrate 110 or a type of transistor, but is not limited thereto.

First, the first transistor T1 is disposed on the buffer layer 111 in each of the plurality of sub pixels SP. The first transistor T1 is a transistor which transmits a data voltage Vdata to the second gate electrode GE2 of the second transistor T2. The first transistor T1 may be turned on by a scan signal from the scan line SL and a data voltage Vdata from the data line DL may be transmitted to the second gate electrode GE2 of the second transistor T2 through the turned-on first transistor T1. Accordingly, the first transistor T1 may be referred to as a switching transistor.

The first transistor T1 includes a first active layer ACT1, a first gate electrode GE1, a first source electrode SE1, and a first drain electrode DE1.

The first active layer ACT1 is disposed on the buffer layer 111. The first active layer ACT1 may be formed of a semiconductor material such as an oxide semiconductor, amorphous silicon, or polysilicon, but is not limited thereto.

The gate insulating layer 112 is disposed on the first active layer ACT1. The gate insulating layer 112 is an insulating layer which insulates the first active layer ACT1 from the first gate electrode GE1 and may be configured by a single layer or a double layer of silicon oxide (SiOx) or silicon nitride (SiNx), but is not limited thereto.

The first gate electrode GE1 is disposed on the gate insulating layer 112. The first gate electrode GE1 may be electrically connected to the scan line SL. The first gate electrode GE1 may be configured by a conductive material, such as copper (Cu), aluminum (Al), molybdenum (Mo), nickel (Ni), titanium (Ti), and chrome (Cr), or an alloy thereof, but is not limited thereto.

The interlayer insulating layer 113 is disposed on the first gate electrode GE1. A contact hole is formed in the interlayer insulating layer 113 to allow the first source electrode SE1 and the first drain electrode DE1 to be connected to the first active layer ACT1. The interlayer insulating layer 113 is an insulating layer which protects components under the interlayer insulating layer 113 and may be configured by a single layer or a double layer of silicon oxide (SiOx) or silicon nitride (SiNx), but is not limited thereto.

A first source electrode SE1 and a first drain electrode DE1 which are electrically connected to the first active layer ACT1 are disposed on the interlayer insulating layer 113. The first drain electrode DE1 may be connected to the data line DL and the first active layer ACT1 and the first source electrode SE1 may be connected to the first active layer ACT1 and the second gate electrode GE2 of the second transistor T2. The first source electrode SE1 and the first drain electrode DE1 may be configured by a conductive material, such as copper (Cu), aluminum (Al), molybdenum (Mo), nickel (Ni), titanium (Ti), and chrome (Cr), or an alloy thereof, but are not limited thereto.

The second transistor T2 is disposed on the buffer layer 111 in each of the plurality of sub pixels SP. The second transistor T2 is a transistor which supplies a driving current to the light emitting diode LED. The second transistor T2 is turned on to control the current flowing to the light emitting diode LED. Accordingly, the second transistor T2 which controls the driving current may be referred to as a driving transistor.

The second transistor T2 includes a second active layer ACT2, a second gate electrode GE2, a second source electrode SE2, and a second drain electrode DE2.

The second active layer ACT2 is disposed on the buffer layer 111. The second active layer ACT2 may be formed of a semiconductor material such as an oxide semiconductor, amorphous silicon, or polysilicon, but is not limited thereto.

The gate insulating layer 112 is disposed on the second active layer ACT2 and the second gate electrode GE2 is disposed on the gate insulating layer 112. The second gate electrode GE2 may be electrically connected to the first source electrode SE1 of the first transistor T1. The second gate electrode GE2 may be configured by a conductive material, such as copper (Cu), aluminum (Al), molybdenum (Mo), nickel (Ni), titanium (Ti), and chrome (Cr), or an alloy thereof, but is not limited thereto.

A size of the second active layer ACT2 may vary depending on a type of the light emitting diode LED which is connected to the second transistor T2. In this case, a type of the light emitting diode LED refers to a type of light to be emitted so that a size of the second active layer ACT2 varies according to a red light emitting diode, a green light emitting diode, and a blue light emitting diode. The larger the size of the second active layer ACT2, the larger the magnitude of the driving current so that the magnitude of the second active layer ACT2 may be determined according to the efficiency of the light emitting diode LED.

For example, in FIG. 3, a size of the second active layer ACT2 disposed in the first sub pixel SP1 is the largest, a size of the second active layer ACT2 disposed in the second sub pixel SP2 is smaller than the size of the second active layer ACT2 disposed in the first sub pixel SP1. Further, a size of the second active layer ACT2 disposed in the third sub pixel SP3 is smaller than the size of the second active layer ACT2 disposed in the second sub pixel SP2. In this case, a light emitting diode LED disposed in the first sub pixel SP1 is a red light emitting diode, a light emitting diode LED disposed in the second sub pixel SP2 is a green light emitting diode, and a light emitting diode LED disposed in the third sub pixel SP3 is a blue light emitting diode, but is not limited thereto.

The interlayer insulating layer 113 is disposed on the second gate electrode GE2 and the second source electrode SE2 and the second drain electrode DE2 which are electrically connected to the second active layer ACT2 are disposed on the interlayer insulating layer 113. The second drain electrode DE2 is electrically connected to the second active layer ACT2 and the high potential power line VL1 and the second source electrode SE2 is electrically connected to the second active layer ACT2 and the light emitting diode LED. The second source electrode SE2 and the second drain electrode DE2 may be configured by a conductive material, such as copper (Cu), aluminum (Al), molybdenum (Mo), nickel (Ni), titanium (Ti), and chrome (Cr), or an alloy thereof, but are not limited thereto.

The third transistor T3 is disposed on the buffer layer 111 in each of the plurality of sub pixels SP. The third transistor T3 is a transistor for compensating for a threshold voltage of the second transistor T2. The third transistor T3 is connected between the second source electrode SE2 of the second transistor T2 and the reference line VL3. The third transistor T3 is turned on to transmit the reference voltage to the second source electrode SE2 of the second transistor T2 to sense a threshold voltage of the second transistor T2. Accordingly, the third transistor T3 which senses a characteristic of the second transistor T2 may be referred to as a sensing transistor.

The third transistor T3 includes a third active layer ACT3, a third gate electrode GE3, a third source electrode SE3, and a third drain electrode DE3.

The third active layer ACT3 is disposed on the buffer layer 111. The third active layer ACT3 may be formed of a semiconductor material such as an oxide semiconductor, amorphous silicon, or polysilicon, but is not limited thereto.

The gate insulating layer 112 is disposed on the third active layer ACT3 and the third gate electrode GE3 is disposed on the gate insulating layer 112. The third gate electrode GE3 may be electrically connected to the scan line SL. The third gate electrode GE3 may be configured by a conductive material, such as copper (Cu), aluminum (Al), molybdenum (Mo), nickel (Ni), titanium (Ti), and chrome (Cr), or an alloy thereof, but is not limited thereto.

The interlayer insulating layer 113 is disposed on the third gate electrode GE3 and the third source electrode SE3 and the third drain electrode DE3 which are electrically connected to the third active layer ACT3 are disposed on the interlayer insulating layer 113. The third drain electrode DE3 may be electrically connected to the third active layer ACT3 and the reference line RL and the third source electrode SE3 may be electrically connected to the third active layer ACT3 and the second source electrode SE2 of the second transistor T2. The third source electrode SE3 and the third drain electrode DE3 may be configured by a conductive material, such as copper (Cu), aluminum (Al), molybdenum (Mo), nickel (Ni), titanium (Ti), and chrome (Cr), or an alloy thereof, but are not limited thereto.

Both the first transistor T1 and the third transistor T3 illustrated in FIG. 3 are transistors which are connected to the scan line SL to be controlled, but are not limited thereto, the pixel circuit may include transistors connected to an emission line EL.

Next, the second capacitor electrode SC2 is disposed on the gate insulating layer 112. The second capacitor electrode SC2 is one of electrodes which form the storage capacitor Cst and may be disposed to overlap with the first capacitor electrode SC1. The second capacitor electrode SC2 is integrally formed with the second gate electrode GE2 of the second transistor T2 to be electrically connected to the second gate electrode GE2. The first capacitor electrode SC1 and the second capacitor electrode SC2 may be disposed to be spaced apart from each other with the buffer layer 111 and the gate insulating layer 112 therebetween.

Further, the plurality of scan lines SL, an auxiliary high potential power line AVL1, a first lower assembly electrode 121, and a third capacitor electrode SC3 are disposed on the interlayer insulating layer 113.

First, the scan line SL is a wiring line which transmits the scan signal SCAN to the plurality of sub pixels SP. The scan line SL may extend in the row direction while traversing the plurality of sub pixels SP. The scan line SL may be electrically connected to the first gate electrode GE1 of the first transistor T1 and the third gate electrode GE3 of the third transistor T3 of each of the plurality of sub pixels SP.

The auxiliary high potential power line AVL1 is disposed on the interlayer insulting layer 113. The auxiliary high potential power line AVL1 extends in the row direction to traverse the plurality of sub pixels SP. The auxiliary high potential power line AVL1 may be electrically connected to the high potential power line VL1 extending in the column direction and the second drain electrode DE2 of the second transistor T2 of each of the plurality of sub pixels SP disposed along the row direction.

The first lower assembly electrode 121 is disposed on the interlayer insulating layer 113. The first lower assembly electrode 121 may be partially formed in an area of the sub pixel SP which overlaps with the light emitting diode LED. The first lower assembly electrode 121 is disposed to overlap with the light emitting diode LED and the second assembly line 123 to be described below and is electrically connected to the second assembly line 123. The first lower assembly electrode 121 is a component disposed in each of the plurality of sub pixels SP and is not shared with the other sub pixels SP.

The third capacitor electrode SC3 is disposed on the interlayer insulating layer 113. The third capacitor electrode SC3 is an electrode which forms the storage capacitor Cst and may be disposed to overlap with the first capacitor electrode SC1 and the second capacitor electrode SC2. The third capacitor electrode SC3 is integrally formed with the second source electrode SE2 of the second transistor T2 to be electrically connected to the second source electrode SE2. Further, the second source electrode SE2 may be electrically connected to the first capacitor electrode SC1 through a contact hole formed in the interlayer insulating layer 113 and the buffer layer 111. Therefore, the first capacitor electrode SC1 and the third capacitor electrode SC3 may be electrically connected to the second source electrode SE2 of the second transistor T2.

The storage capacitor Cst stores a potential difference between the second gate electrode GE2 and the second source electrode SE2 of the second transistor T2 while the light emitting diode LED emits light, so that a constant current is supplied to the light emitting diode LED. The storage capacitor Cst includes the first capacitor electrode SC1, the second capacitor electrode SC2, and the third capacitor electrode SC3 to store a voltage between the second gate electrode GE2 and the second source electrode SE2 of the second transistor T2. The first capacitor electrode SC1 is formed on the substrate 110 and is connected to the second source electrode SE2 and the second capacitor electrode SC2 is formed on the buffer layer 111 and the gate insulating layer 112 and is connected to the second gate electrode GE2. The third capacitor electrode SC3 is formed on the interlayer insulating layer 113 and is connected to the second source electrode SE2.

The first passivation layer 114 is disposed on the first transistor T1, the second transistor T2, the third transistor T3, and the storage capacitor Cst. The first passivation layer 114 is an insulating layer which protects components under the first passivation layer 114 and may be configured by a single layer or a double layer of silicon oxide (SiOx) or silicon nitride (SiNx), but is not limited thereto.

The first planarization layer 115 is disposed on the first passivation layer 114. The first planarization layer 115 may planarize an upper portion of the substrate 110 on which the plurality of transistors T1, T2, and T3 and the storage capacitor Cst are disposed. The first planarization layer 115 may be configured by a single layer or a double layer, and for example, may be formed of photoresist or an acrylic-based organic material, but is not limited thereto.

The first planarization layer 115 and the first passivation layer 114 include an assembly groove LH1 for disposing the light emitting diode LED. The first planarization layer 115 and the first passivation layer 114 expose a part of the first lower assembly electrode 121 while covering an edge of the first lower assembly electrode 121. The assembly groove LH1 is an area formed by removing the first planarization layer 115 and the first passivation layer 114 and a part of the first lower assembly electrode 121 and a part of the interlayer insulating layer are exposed. The assembly groove LH1 may be formed to have the same shape as a shape of the light emitting diode LED disposed in the assembly groove LH1. A size of the assembly groove LH1 is almost equal to or larger than the size of the light emitting diode LED so that the light emitting diode LED is disposed in the assembly groove LH1.

The second passivation layer 116 is disposed on the first planarization layer 115. Specifically, the second passivation layer 116 is disposed not only on the first planarization layer 115, but also on the first lower assembly electrode 121 and the interlayer insulating layer 114 disposed in the assembly groove LH1. The second passivation layer 116 is an insulating layer which protects components under the second passivation layer 116 and may be configured by a single layer or a double layer of silicon oxide (SiOx) or silicon nitride (SiNx), but is not limited thereto.

The connection electrode 120, the plurality of first assembly lines 122, and the plurality of second assembly lines 123 are disposed on the second passivation layer 116.

First, the connection electrode 120 is disposed in each of the plurality of sub pixels SP. The connection electrode 120 is an electrode which electrically connects the second transistor T2 and the pixel electrode PE. The connection electrode 120 may be electrically connected to the second source electrode SE2 which also serves as the third capacitor electrode SC3 through a contact hole formed in the second passivation layer 116, the first planarization layer 115, and the first passivation layer 114.

The connection electrode 120 may have a double layered structure formed by a first connection layer 120a and a second connection layer 120b. The first connection layer 120a is disposed on the second passivation layer 116 and the second connection layer 120b which covers the first connection layer 120a is disposed. The second connection layer 120b may be disposed to enclose all a top surface and side surfaces of the first connection layer 120a. The second connection layer 120b is formed of a material which is more resistant to corrosion than the first connection layer 120a so that when the display device 100 is manufactured, the short defect due to the migration between the first connection layer 120a and the adjacent wiring line may be minimized. For example, the first connection layer 120a is formed of a conductive material, such as copper (Cu) or chrome (Cr) and the second connection layer 120b is formed of molybdenum (Mo) or titanium molybdenum (MoTi), but are not limited thereto.

A plurality of assembly lines AL is disposed on the second passivation layer 116. Specifically, the plurality of assembly lines AL is disposed on the first planarization layer 115 disposed in the vicinity of the assembly groove LH1. The plurality of assembly lines AL is wiring lines which transmit a low potential power voltage to the light emitting diode LED. The plurality of assembly lines AL may extend in the column direction in each of the plurality of sub pixels SP. For example, one pair of assembly lines AL which are spaced apart from each other with a predetermined interval may be disposed in each of the first sub pixel SP1, the second sub pixel SP2, and the third sub pixel SP3. One pair of assembly lines AL may include a first assembly line 122 and a second assembly line 123. Any one of the first assembly line 122 and the second assembly line 123 is disposed to overlap with the first lower assembly electrode 121. In FIG. 4, even though it is illustrated that the second assembly line 123 is disposed to overlap with the first lower assembly electrode 121, but is not limited thereto.

Each of the plurality of assembly lines AL includes a conductive layer and a clad layer. The conductive layer is disposed on the second passivation layer 116 and the clad layer which covers all a top surface and side surfaces of the conductive layer is disposed on the conductive layer. Specifically, a first conductive layer 122a and a second conductive layer 123a are disposed on the second passivation layer 116 and a first clad layer 122b and a second clad layer 123b are disposed on the first conductive layer 122a and the second conductive layer 123a. For example, the first conductive layer 122a and the second conductive layer 123a may be formed of a conductive material, such as copper (Cu) and chrome (Cr). Further, the first clad layer 122b and the second clad layer 123b are formed of a material which is more resistant to corrosion than the first conductive layer 122a and the second conductive layer 123a, for example, molybdenum (Mo) or titanium molybdenum (MoTi), but is not limited thereto.

Specifically, the first clad layer 122b is disposed on a side surface of the first planarization layer 115 and in the assembly groove LH1 while covering the top surface and side surfaces of the first conductive layer 122a. The first clad layer 122b disposed in the assembly groove LH1 overlaps with the light emitting diode LED. The first clad layer 122b which is disposed on the side surface of the first planarization layer 115 and in the assembly groove LH1 may not entirely cover the side surface of the first planarization layer 115 and the inside of the assembly groove LH1, but may be disposed only in an area corresponding less than half thereof. Further, the second clad layer 123b covers the top surface and side surfaces of the second conductive layer 123a, but is not disposed on a side surface of the first planarization layer 115 and inside of the assembly groove LH1.

The first clad layer 122b and the first lower assembly electrode 121 disposed in the assembly groove LH1 are disposed on different layers so that an interval between the first clad layer 122b and the first lower assembly electrode 121 may be reduced. To assemble the light emitting diode LED, as the interval between assembly electrodes disposed in the assembly groove LH1 is narrow, the intensity of the electric field is increased to improve the assembling power. When the first clad layer 122b and the first lower assembly electrode 121 are disposed on the same layer, it is restricted to reduce the interval between the first clad layer 122b and the first lower assembly electrode 121. Accordingly, in the display device 100 according to the exemplary aspect of the present disclosure, the first clad layer 122b and the first lower assembly electrode 121 which are formed in the assembly groove LH1 to form an electric field are disposed on different layers. Therefore, the assembling power for assembling the light emitting diode LED may be improved.

The second conductive layer 123a disposed in each of the plurality of sub pixels SP is electrically connected to the first lower assembly electrode 121 through a line contact electrode LCE. The line contact electrode LCE is disposed in a line contact hole LH2 formed in the second passivation layer 116, the first planarization layer 115, and the first passivation layer 114. The line contact hole LH2 may be formed by performing a contact hole forming process two times. A first line contact hole LH2a is formed by a first contact hole forming process and a second line contact hole LH2b may be formed by a second contact hole forming process. The first line contact hole LH2a is a contact hole formed in the first planarization layer 115 and the first passivation layer 114 and the second line contact hole LH2b is a contact hole formed in the second passivation layer 116. That is, the line contact hole LH2 may include the first line contact hole LH2a and the second line contact hole HL2b. In this case, a size of the first line contact hole LH2a is larger than a size of the second line contact hole LH2b to align the first line contact hole LH2a and the second line contact hole LH2b.

In the meantime, the second lower assembly electrode 125 is disposed on the second passivation layer 116. The second lower assembly electrode 125 may be formed by the same material by the same process as the first clad layer 122b, the second clad layer 123b, and the second connection layer 120b. The second lower assembly electrode 125 is disposed in the assembly groove LH1 to be in direct contact with the light emitting diode LED. Further, the second lower assembly electrode 125 is spaced apart from the first clad layer 122b and partially overlaps with the first lower assembly electrode 121. Before disposing the light emitting diode LED, the second lower assembly electrode 125 is floated to be coupled to a signal applied through the first lower assembly electrode 121 to serve as an assembly line. Not only the assembly line AL, but also both the first lower assembly electrode 121 which is electrically connected to the assembly line AL and the second lower assembly electrode 125 coupled to the first lower assembly electrode 121 form an electric field to self-assemble the light emitting diode LED.

The third passivation layer 117 is disposed on the connection electrode 120 and the assembly line AL. Specifically, the third passivation layer 117 exposes the entire second lower assembly electrode 125 and a part of the assembly line AL to the outside. The third passivation layer 117 is an insulating layer which protects components under the third passivation layer 117 and may be configured by a single layer or a double layer of silicon oxide (SiOx) or silicon nitride (SiNx), but is not limited thereto.

Next, the plurality of light emitting diodes LED is disposed on the third passivation layer 117 and the second lower assembly electrode 125. The light emitting diodes LED are disposed in the assembly groove LH1. One or more light emitting diodes LED are disposed in one sub pixel SP. The light emitting diode LED is an element which emits light by the current. The light emitting diode LED may include a light emitting diode LED which emits red light, green light, and blue light and implement various color light including white by a combination thereof. Further, various color light may be implemented using the light emitting diode LED which emits specific color light and a light conversion member which converts light from the light emitting diode LED into another color light. The light emitting diode LED is electrically connected between the second transistor T2 and the assembly line AL and is supplied with a driving current from the second transistor T2 to emit light.

At this time, the plurality of light emitting diodes LED disposed in one sub pixel SP may be connected in parallel. That is, one electrode of each of the plurality of light emitting diodes LED is connected to the same source electrode of the second transistor T2 and the other electrode is connected to the same assembly line AL.

In the meantime, the light emitting diode LED disposed in each of the plurality of sub pixels may have a different structure. For example, the light emitting diode LED may include a first light emitting diode 130 and a second light emitting diode 140. The first light emitting diode 130 may be disposed in the first sub pixel SP, among the plurality of sub pixels SP and the second light emitting diode 140 may be disposed in the second sub pixel SP2 and the third sub pixel SP3, among the plurality of sub pixels SP. However, the type of the light emitting diode LED is illustrative and only any one of the first light emitting diode 130 or the second light emitting diode 140 is used as the light emitting diode LED or another type of light emitting diode may be used, but is not limited thereto. Further, even though in FIGS. 4 and 5, for the convenience of description, it is illustrated that two light emitting diodes LED are disposed in each of the plurality of sub pixels SP, the number of light emitting diodes LED which is disposed in each of the plurality of sub pixels SP is not limited thereto.

Referring to FIG. 4, the first light emitting diode 130, among the plurality of light emitting diodes LED, includes a first semiconductor layer 131, an emission layer 132, a second semiconductor layer 133, a first electrode 134, a second electrode 135, and an encapsulation layer 136.

The first semiconductor layer 131 is disposed on the third passivation layer 117 and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may be layers formed by doping p-type or n-type impurity into a material, such as gallium nitride (GaN), indium aluminum phosphide (InAlP), and gallium arsenide (GaAs). Further, the p-type impurity may be magnesium (Mg), zinc (Zn), beryllium (Be), and the like, and the n-type impurity may be silicon (Si), germanium (Ge), tin (Sn), and the like, but are not limited thereto.

A part of the first semiconductor layer 131 may be disposed to outwardly protrude from the second semiconductor layer 133. An upper surface of the first semiconductor layer 131 may be formed by a part overlapping with a lower surface of the second semiconductor layer 133 and a part disposed at an outside of the lower surface of the second semiconductor layer 133. However, sizes and shapes of the first semiconductor layer 131 and the second semiconductor layer 133 are modified in various forms, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 may be formed by a single layer or a multi-quantum well (MQW) structure, and for example, may be formed of indium gallium nitride (InGaN), gallium nitride (GaN), or the like, but is not limited thereto.

The first electrode 134 which encloses a bottom surface and side surfaces of the first semiconductor layer 131 is disposed. The first electrode 134 is an electrode which electrically connects the first light emitting diode 130 and the assembly line AL. The first electrode 134 may be configured by a conductive material, for example, a transparent conductive material, such as indium tin oxide (ITO) and indium zinc oxide (IZO) or an opaque conductive material, such as titanium (Ti), gold (Au), silver (Ag), and copper (Cu) or an alloy thereof, but is not limited thereto.

The second electrode 135 is disposed on the top surface of the second semiconductor layer 133. The second electrode 135 is an electrode which electrically connects a pixel electrode PE to be described below and the second semiconductor layer 133. The second electrode 135 is formed of a conductive material, for example, a transparent conductive material, such as indium tin oxide (ITO) or indium zinc oxide (IZO), but is not limited thereto.

The encapsulation layer 136 which encloses at least a part of the first semiconductor layer 131, the emission layer 132, the second semiconductor layer 133, the first electrode 134, and the second electrode 135 is disposed. The encapsulation layer 136 is formed of an insulating material to protect the first semiconductor layer 131, the emission layer 132, and the second semiconductor layer 133. The encapsulation layer 136 may be disposed to cover the emission layer 132, a part of a side surface of the first semiconductor layer 131 adjacent to the emission layer 132, and a part of a side surface of the second semiconductor layer 133 adjacent to the emission layer 132. The first electrode 134 and the second electrode 135 are exposed from the encapsulation layer 136 and a chip contact electrode CCE to be formed later and a pixel electrode PE and the first electrode 134 and the second electrode 135 may be electrically connected.

Referring to FIG. 5, the second light emitting diode 140 includes a first semiconductor layer 141, an emission layer 142, a second semiconductor layer 143, a first electrode 144, a second electrode 145, and an encapsulation layer 146. The first semiconductor layer 141, the emission layer 142, the second semiconductor layer 143, the second electrode 145, and the encapsulation layer 146 of the second light emitting diode 140 are substantially the same as the first semiconductor layer 131, the emission layer 132, the second semiconductor layer 133, the second electrode 135, and the encapsulation layer 136 of the first light emitting diode 130. However, the only difference between the second light emitting diode 140 and the first light emitting diode 130 is a structure of the first electrode 144, but the other configuration is substantially the same.

The first electrode 144 of the second light emitting diode 140 is disposed to be in contact only with a bottom surface of the first semiconductor layer 141. As compared with the first light emitting diode 130 in which the first electrode 134 covers both the bottom surface and the side surface of the first semiconductor layer 131, in the second light emitting diode 140, the first electrode 144 is disposed only on the bottom surface of the first semiconductor layer 141. Therefore, the side surface of the first semiconductor layer 141 of the second light emitting diode 140 may be exposed from the first electrode 144. Therefore, the chip contact electrode CCE is in contact with the side surface of the first semiconductor layer 141 and the side surface of the first electrode 144 to be electrically connected to the second light emitting diode 140.

Next, an adhesive layer may be disposed between the plurality of light emitting diodes LED and the third passivation layer 117 and the second lower assembly electrode 125. The adhesive layer may be an organic film which temporarily fixes the light emitting diode LED during the self-assembly process of the light emitting diode LED. When the display device 100 is manufactured, if an organic film which covers the light emitting diode LED is formed, a part of the organic film is filled in a space between the light emitting diode LED and the third passivation layer 117 and the second lower assembly electrode 125 to temporary fix the light emitting diode LED onto the third passivation layer 117 and the second lower assembly electrode 125. Thereafter, even though the organic film is removed, a part of the organic film which permeates under the light emitting diode LED remains without being removed to serve as an adhesive layer. The adhesive layer may be formed of an organic material, for example, photoresist or an acrylic-based organic material, but is not limited thereto.

The chip contact electrode CCE is disposed on the side surface of the light emitting diode LED. The chip contact electrode CCE is an electrode which electrically connects the light emitting diode LED and the assembly line AL and is also disposed above the assembly line AL in which the third passivation layer 117 is not disposed and on the second passivation layer 116 disposed on the side surface of the assembly groove LH1. The chip contact electrode CCE may also cover the edge of the assembly line AL. The chip contact electrode CCE is disposed to enclose at least a part of the first semiconductor layers 131 and 141 and the first electrodes 134 and 144 to electrically connect the first semiconductor layers 131 and 141 and the first electrodes 134 and 144 and the assembly line AL. In this case, the chip contact electrode CCE is also connected to the second lower assembly electrode 125. To electrically connect the second assembly line 123 and the light emitting diode LED, the second lower assembly electrode 125 which is in direct contact with the bottom surface of the first electrodes 134 and 144 is also connected to reduce a contact resistance of the second assembly line 123. Therefore, a lighting rate of the light emitting diode LED may be improved. The lighting rate may refer to the ratio of the number of light emitting diodes LED which emit light normally among all the light emitting diodes LED disposed on the display panel.

Next, the second planarization layer 118 is disposed on the light emitting diode LED and the chip contact electrode CCE. The second planarization layer 118 planarizes an upper portion of the substrate 110 in which the light emitting diode LED is disposed and may fix the light emitting diode LED onto the substrate 110 together with the adhesive layer. The light emitting diode LED included in the display device 100 according to the exemplary aspect of the present disclosure is disposed in the assembly groove LH1 formed in the first planarization layer 115 to reduce the thickness of the second planarization layer 118 and be implemented by a single layer. However, it is not limited thereto and the second planarization layer 118 may be configured by a single layer or a double layer, and for example, may be formed of photoresist or an acrylic-based organic material, but is not limited thereto.

A protection layer 119 is disposed on the second planarization layer 118 and the light emitting diode LED. The protection layer 119 is disposed in an area excluding a part of the second electrodes 135 and 145 of the light emitting diode LED. The protection layer 119 is an insulating layer which protects components under the protection layer 119 and may be configured by a single layer or a double layer of silicon oxide (SiOx) or silicon nitride (SiNx), but is not limited thereto.

The pixel electrode 142 is disposed on the protection layer 119. The pixel electrode PE is an electrode which electrically connects the plurality of light emitting diodes LED and the connection electrode 120. The pixel electrode PE may be electrically connected to the light emitting diode LED, the connection electrode 120, and the second transistor T2 through the contact hole formed in the second planarization layer 118. Accordingly, the second electrodes 135 and 145 of the light emitting diodes LED, the connection electrode 120, and the second source electrode SE2 of the second transistor T2 may be electrically connected to each other by means of the pixel electrode PE. The pixel electrode PE may be formed of a conductive material, for example, a transparent conductive material, such as indium tin oxide (ITO) or indium zinc oxide (IZO), but is not limited thereto.

In the display device 100 according to the exemplary aspect of the present disclosure, one pair of assembly lines AL disposed in each of the plurality of sub pixels SP, the first lower assembly electrode 121 connected to any one of the pair of assembly lines AL, and the second lower assembly electrode 125 disposed to overlap with the first lower assembly electrode 121 are electrodes for self-assembling the light emitting diode LED. When the display device 100 is manufactured, the first lower assembly electrode 121 and the second lower assembly electrode 125 form an electric field together with one pair of assembly lines AL to self-assemble the light emitting diode LED.

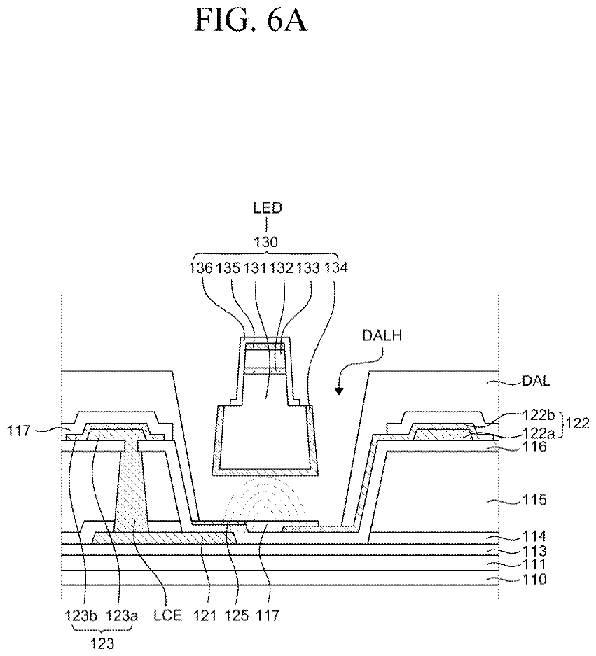

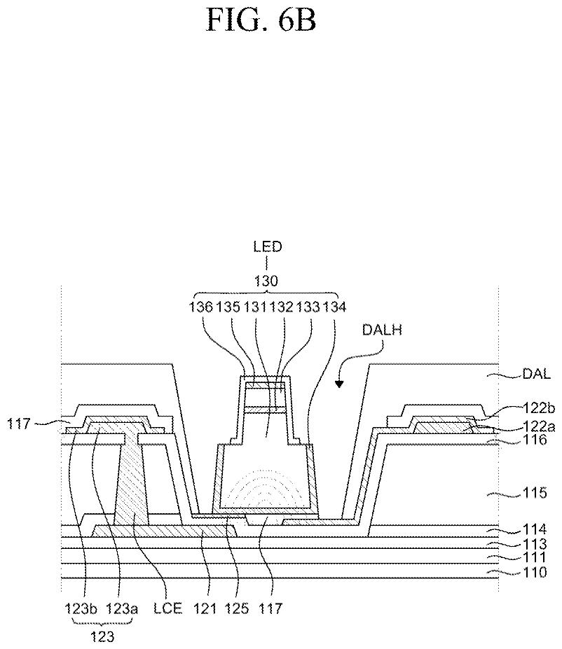

Hereinafter, a self-assembling method of a light emitting diode LED of a display device 100 according to an exemplary aspect of the present disclosure will be described with reference to FIGS. 6A and 6B.

FIGS. 6A and 6B are cross-sectional views for explaining a manufacturing process of a display device according to an exemplary aspect of the present disclosure.

First, referring to FIG. 6A, the buffer layer 111 and the interlayer insulating layer 113 are formed on the substrate 110 and the first lower assembly electrode 121 is formed on the interlayer insulating layer 113.

Next, the first passivation layer 114, the first planarization layer 115, and the second passivation layer 116 are sequentially formed on the first lower assembly electrode 121. Further, the assembly electrode AL and the second lower assembly electrode 125 are formed on the second passivation layer 116.

After completing the manufacturing of the display device 100, the second assembly line 123, the first lower assembly electrode 121, and the second lower assembly electrode 125 may serve as one pair of low potential power lines. During the manufacturing process of the display device 100, different voltages are applied to two adjacent assembly electrodes AL and after completing the manufacturing process of the display device 100, a same low potential power voltage may be applied to two adjacent assembly electrodes AL.

The first assembly line 122 disposed on the second passivation layer 116 includes a first conductive layer 122a and a first clad layer 122b which covers the first conductive layer 122a.

The second assembly line 123 is disposed on the second passivation layer 116. The second assembly line 123 includes a second conductive layer 123a and a second clad layer 123b which covers the second conductive layer 123a. The second conductive layer 123a of the second assembly electrode 123 may be electrically connected to the first lower assembly electrode 125 through a contact hole formed in the second passivation layer 116, the first planarization layer 115, and the first passivation layer 114. Accordingly, the formation of the assembly electrode including the assembly line AL and the lower assembly electrodes 121 and 125 may be completed.

Next, the third passivation layer 117 is formed on the assembly electrode AL and an organic layer DAL having an opening DALH is formed on the third passivation layer 117. The opening DALH of the organic layer DAL may correspond to an area in which the light emitting diode LED is self-assembled. The opening DALH of the organic layer DAL may overlap with the assembly line AL and the lower assembly electrodes 121 and 125. After completing the self-assembling of the light emitting diode LED, the organic layer DAL is removed so as not to be present in the finished display device 100 during the manufacturing process.

The substrate 110 on which the organic layer DAL is formed and the light emitting diode LED are injected into a chamber filled with fluids and an AC voltage is applied to the assembly electrode including the assembly line AL and the lower assembly electrodes 121 and 125 to form an electric field. For example, the same voltage is applied to the second assembly line 123 and the first lower assembly electrode 121 and the second lower assembly electrode 125 is coupled to the first lower assembly electrode 121 to form a voltage also in the second lower assembly electrode 125 to serve as an assembly electrode. Al electric field may be formed between the first assembly line 122 and the second assembly line 123, the first lower assembly electrode 121, and the second lower assembly electrode 125.

The light emitting diode LED is dielectrically polarized by the electric field to have a polarity. Further, the dielectrically polarized light emitting diode LED may move or may be fixed to a specific direction by dielectrophoresis (DEP), that is, an electric field. Accordingly, the plurality of light emitting diodes LED may be self-assembled in the opening DALH above the assembly line AL and the lower assembly electrodes 121 and 125 using the dielectrophoresis.

After self-assembling the light emitting diode LED in the opening DALH, the first electrodes 134 and 144 of the light emitting diode LED and the second lower assembly electrode 125 are conducted while being in contact with each other. Therefore, the second lower assembly electrode 125 is in the same state as being integrated with the first electrodes 134 and 144. Therefore, the light emitting diode LED may be stably fixed to the substrate 110 after being self-assembled.

Finally, when the self-assembling of the light emitting diode LED is completed, the organic layer DAL is removed and another configuration, such as the second planarization layer 118 and the pixel electrode PE, is formed to complete the manufacturing process of the display device 100.

In the meantime, the dielectrophoresis force is proportional to a size of the light emitting diode LED and an intensity of the electric field. The larger the size of the light emitting diode LED or the larger the intensity of the electric field, the stronger the dielectrophoresis acts to improve the assembly rate.

Accordingly, in the display device 100 according to the exemplary aspect of the present disclosure, to increase the dielectrophoresis, the intensity of the electric field may be increased. As described above, the first lower assembly electrode 121 and the first clad layer 122b are disposed on different layers to reduce the interval between the first lower assembly electrode 121 and the first clad layer 122b, thereby increasing the intensity of the electric field and improving the self-assembly rate.

The exemplary aspects of the present disclosure may also be described as follows:

According to an aspect of the present disclosure, a display device includes a substrate including a plurality of sub pixels; a first lower assembly electrode in the plurality of sub pixels; a first assembly line in the plurality of sub pixels and disposed on a layer different from that of the first lower assembly electrode; a light emitting diode on the first lower assembly electrode and the first assembly line and including a first electrode, a semiconductor layer, and a second electrode; and a second lower assembly electrode between the first lower assembly electrode and the light emitting diode and electrically connected to the first electrode or the second electrode.

The first lower assembly electrode and the second lower assembly electrode may be electrically connected.

The first assembly line and the first electrode may be electrically connected. The display device may further include a chip contact electrode which connects the first assembly line and the first electrode. The chip contact electrode may be in contact with a side surface of the light emitting diode. The first assembly line may be connected to a low potential power pad to which a low potential power is applied.

The display device may further include a planarization layer covering a part of the first lower assembly electrode and including an assembly groove. The light emitting diode may be disposed in the assembly groove. The display device may further include a second assembly line disposed on the planarization layer. The second assembly line may be connected to the first lower assembly electrode through a contact hole of the planarization layer. The second assembly line may be connected to a low potential power pad to which a low potential power is applied. The first assembly line may include a first conductive layer on the planarization layer and a first clad layer covering the first conductive layer, and the second assembly line may include a second conductive layer on the planarization layer and a second clad layer covering the second conductive layer.

According to another aspect of the present disclosure, a display device includes a substrate including a plurality of sub pixels; a first assembly line and a second assembly line disposed in parallel in the plurality of sub pixels; a light emitting diode disposed to overlap with the first assembly line or the second assembly line; and a first lower auxiliary electrode and a second lower auxiliary electrode overlapping with the light emitting diode and any one of the first assembly line and the second assembly line, under the light emitting diode.

A plurality of sub pixels disposed in a first direction on the substrate share the first assembly line and the second assembly line.

The display device may further include a low potential voltage pad on one surface of the substrate and to which a low potential power is applied. The first assembly line and the second assembly line may be connected to the low potential voltage pad.

A plurality of light emitting diodes may be provided and at least two light emitting diodes may be disposed in each of the plurality of sub pixels.

The display device may further include a driving transistor on the substrate and electrically connected to the light emitting diode. The driving transistor may be disposed in each of the plurality of sub pixels and sizes of the driving transistors in at least two sub pixels may be different.

The light emitting diode may include a first electrode, a semiconductor layer, and a second electrode, and the second lower auxiliary electrode may be disposed between the first lower auxiliary electrode and the light emitting diode to be in contact with the first electrode or the second electrode.

Although the exemplary aspects of the present disclosure have been described in detail with reference to the accompanying drawings, the present disclosure is not limited thereto and may be embodied in many different forms without departing from the technical concept of the present disclosure. Therefore, the exemplary aspects of the present disclosure are provided for illustrative purposes only but not intended to limit the technical concept of the present disclosure. The scope of the technical concept of the present disclosure is not limited thereto. Therefore, it should be understood that the above-described exemplary aspects are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including a plurality of sub pixels;
a first lower assembly electrode disposed in the plurality of sub pixels;
a first assembly line disposed in the plurality of sub pixels and disposed on a layer different from that of the first lower assembly electrode;
a light emitting diode disposed on the first lower assembly electrode and the first assembly line and including a first electrode, a semiconductor layer and a second electrode; and
a second lower assembly electrode disposed between the first lower assembly electrode and the light emitting diode and electrically connected to the first electrode or the second electrode.

2. The display device according to claim 1, wherein the first lower assembly electrode and the second lower assembly electrode are electrically connected.

3. The display device according to claim 1, wherein the first assembly line and the first electrode are electrically connected.

4. The display device according to claim 3, further comprising a chip contact electrode which connects the first assembly line and the first electrode,
wherein the chip contact electrode is in contact with a side surface of the light emitting diode.

5. The display device according to claim 3, wherein the first assembly line is connected to a low potential power pad to which a low potential power is applied.

6. The display device according to claim 1, further comprising a planarization layer covering a part of the first lower assembly electrode and including an assembly groove,
wherein the light emitting diode is disposed in the assembly groove.

7. The display device according to claim 6, further comprising a second assembly line disposed on the planarization layer,
wherein the second assembly line is connected to the first lower assembly electrode through a contact hole of the planarization layer.

8. The display device according to claim 7, wherein the second assembly line is connected to a low potential power pad to which a low potential power is applied.

9. The display device according to claim 7, wherein the first assembly line includes a first conductive layer disposed on the planarization layer and a first clad layer covering the first conductive layer, and
wherein the second assembly line includes a second conductive layer disposed on the planarization layer and a second clad layer covering the second conductive layer.

10. A display device, comprising:
a substrate including a plurality of sub pixels;
a first assembly line and a second assembly line disposed in parallel in the plurality of sub pixels;
a plurality of light emitting diodes disposed on the substrate and each light emitting diode overlapping with the first assembly line or the second assembly line; and
a first lower auxiliary electrode and a second lower auxiliary electrode overlapping with the light emitting diode and one of the first assembly line and the second assembly line, under the light emitting diode.

11. The display device according to claim 10, wherein the plurality of sub pixels disposed in a first direction on the substrate share the first assembly line and the second assembly line.

12. The display device according to claim 10, further comprising a low potential voltage pad disposed on one surface of the substrate and to which a low potential power is applied,
wherein the first assembly line and the second assembly line are connected to the low potential voltage pad.

13. The display device according to claim 10, wherein at least two light emitting diodes are disposed in each of the plurality of sub pixels.

14. The display device according to claim 10, further comprising a driving transistor on the substrate and electrically connected to the light emitting diode.

15. The display device according to claim 14, wherein the driving transistor is disposed in each of the plurality of sub pixels and
wherein sizes of the driving transistors in at least two sub pixels are different.

16. The display device according to claim 10, wherein each light emitting diode includes a first electrode, a semiconductor layer, and a second electrode, and
wherein the second lower auxiliary electrode is disposed between the first lower auxiliary electrode and the light emitting diode to be in contact with the first electrode or the second electrode.
